(19) United States
(12) Patent Application Publication
(10) Pub. No.: US 2012/0147669 A1
(43) Pub. Date: Jun. 14, 2012

(54) NON-VOLATILE MEMORY DEVICE AND A METHOD FOR OPERATING THE DEVICE

(76) Inventor: Dae-Seok Byeon, Suwon-si (KR)

(21) Appl. No.: 13/303,819

(22) Filed: Nov. 23, 2011

(30) Foreign Application Priority Data
Dec. 14, 2010 (KR) 10-2010-00127636

(51) Int. Cl. G11C 16/10; G11C 16/04

(52) U.S. Cl. 365/185.03; 365/185.18

(57) ABSTRACT

A method for operating a non-volatile memory device includes programming a memory cell and not programming a flag cell during first to n^{th} (n is a natural number equal to or greater than 1) program loops, and programming the memory cell and the flag cell during (n+1)^{th} to m^{th} (m is a natural number greater than n) program loops.

### CROSS-REFERENCE TO RELATED APPLICATION

This application claims priority under 35 U.S.C. §119 to Korean Patent Application No. 10-2010-0127636 filed on Dec. 14, 2010 in the Korean Intellectual Property Office, the disclosure of which is incorporated by reference herein in its entirety.

### BACKGROUND

1. Technical Field

The present inventive concept relates to a non-volatile memory device and a method for operating the device.

2. Discussion of the Related Art

Semiconductor memory devices may be classified as volatile memory devices and non-volatile memory devices.

Volatile memory devices can perform data read/write operations quickly, but they lose data when their external power supply is interrupted, for example, when the power supply is switched-off. On the other hand, non-volatile memory devices can store data even when their external power supply is interrupted. Accordingly, non-volatile memory devices store data regardless of a state of a power supply. Exemplary non-volatile memory devices may include a mask read-only memory (MROM), a programmable read-only memory (PROM), an erasable programmable read-only memory (EPROM), an electrically erasable programmable read-only memory (EEPROM) and the like.

In general, MROM, PROM and EPROM are programmed by the manufacturer, rather than by ordinary users. On the other hand, EEPROM is able to be electrically erased and reprogrammed by an ordinary user, and thus it is widely used as an auxiliary storage device or system programming requiring continuous updating. Particularly, since a flash EEPROM has a higher integration than a conventional EEPROM, it is very often used as a large capacity auxiliary storage device. Among the flash EEPROMs, a NAND type flash EEPROM (hereinafter, referred to as a “NAND flash memory”) has a high integration as compared to other EEPROMs.

In a flash memory device, such as a NAND flash memory, a state of data that can be stored in a memory cell is determined according to bits stored in the memory cell. A memory cell storing 1-bit of data is referred to as a single-bit cell or single-level cell (SLC), for example. Further, a memory cell storing multiple bits (e.g., 2-bits or more) of data is referred to as a multi-bit cell, multi-level cell (MLC) or multi-state cell, for example. Since the demand for high integration memory devices is increasing, there is a need to improve a flash memory that stores multiple bits of data in one memory cell.

### SUMMARY

The present inventive concept provides a method for operating a non-volatile memory device capable of ensuring data reliability in the event of a sudden power-off.

The present inventive concept also provides a non-volatile memory device capable of ensuring data reliability in the event of a sudden power-off.

According to an exemplary embodiment of the present inventive concept, there is provided a method for operating a non-volatile memory device including programming a memory cell and not programming a flag cell during first to n^{th} (n is a natural number equal to or greater than 1) program loops, and programming the memory cell and the flag cell during (n+1)^{th} to m^{th} (m is a natural number greater than n) program loops.

The method further including programming an error detection cell during the first to n^{th} program loops.

The memory cell includes a 2-bit multi-level cell.

The memory cell has ‘11’, ‘10’, ‘00’ and ‘01’ states, a first read voltage is set between the ‘11’ state and the ‘01’ state, a second read voltage is set between the ‘01’ state and the ‘00’ state, a third read voltage is set between the ‘00’ state and the ‘10’ state, the memory cell has the ‘11’ or ‘10’ state in a least significant bit (LSB) programming, and the memory cell has the ‘11’, ‘10’, ‘00’ or ‘01’ state in a most significant bit (MSB) programming.

In the MSB programming, a threshold voltage of the flag cell is greater than the second read voltage.

The flag cell determines whether the memory cell has been MSB programmed.

Each of the first to m^{th} program loops includes a program section and a verify section, and a first program voltage and a second program voltage are applied to the memory cell during the program section.

The first program voltage programs the memory cell from the ‘11’ state to the ‘01’ state, and the second program voltage programs the memory cell from the ‘10’ state to the ‘00’ or ‘10’ state.

The method further includes reading LSB data of the memory cell, wherein the reading includes: comparing a threshold voltage of the flag cell with the second read voltage; comparing a threshold voltage of the memory cell with the first read voltage if the threshold voltage of the flag cell is not greater than the second read voltage; and comparing the threshold voltage of the memory cell with the second read voltage if the threshold voltage of the flag cell is greater than the second read voltage.

If the threshold voltage of the memory cell is greater than the first read voltage the LSB data read from the memory cell is if the threshold voltage of the memory cell is not greater than the first read voltage the LSB data read from the memory cell is ‘1’ if the threshold voltage of the memory cell is greater than the second read voltage the LSB data read from the memory cell is or if the threshold voltage of the memory cell is not greater than the second read voltage the LSB data read from the memory cell is ‘1.’

The method further includes reading MSB data of the memory cell, wherein the reading includes: comparing a threshold voltage of the flag cell with the first read voltage; comparing a threshold voltage of the memory cell with the first read voltage if the threshold voltage of the flag cell is greater than the first read voltage; and comparing the threshold voltage of the memory cell with the third read voltage if the threshold voltage of the memory cell is greater than the first read voltage.

If the threshold voltage of the memory cell is not greater than the third read voltage the MSB data read from the memory cell is ‘0,’ if the threshold voltage of the flag cell is not greater than the first read voltage the MSB data read from the memory cell is ‘1,’ if the threshold voltage of the memory cell is not greater than the first read voltage the MSB data read from the memory cell is ‘1’ or if the threshold voltage of the memory cell is greater than the third read voltage the MSB data read from the memory cell is ‘1.’

The memory cell includes a NAND flash memory cell.

According to an exemplary embodiment of the present inventive concept, there is provided a method for operating a non-volatile memory device including programming a memory cell and not programming a flag cell during a first period, and programming the memory cell and the flag cell during a second period after the first period.

The memory cell includes a 2-bit memory cell.

The memory cell has ‘11’, ‘10’, ‘00’ and ‘01’ states, a first read voltage is set between the ‘11’ state and the ‘01’ state, a second read voltage is set between the ‘01’ state and the ‘00’ state, a third read voltage is set between the ‘00’ state and the ‘10’ state, the memory cell has the ‘11’ or ‘10’ state in a least significant bit (LSB) programming, and the memory cell has the ‘11’, ‘10’, ‘00’ or ‘01’ state in a most significant bit (MSB) programming.

The flag cell determines whether the memory cell has been MSB programmed.

According to an exemplary embodiment of the present inventive concept, there is provided a non-volatile memory device including a memory core including a memory cell and a flag cell, and a read-write module, wherein the read-write module programs the memory cell and prevents the flag cell from being programmed during first to n^{th} (n is a natural number equal to or greater than 1) program loops, and programs the memory cell and the flag cell during (n+1)^{th}, m^{th} (m is a natural number greater than n) program loops.

The memory cell stores 2 or more bits.

The memory cell includes a NAND flash memory cell.

### BRIEF DESCRIPTION OF THE DRAWINGS

The above and other features of the present inventive concept will become more apparent by describing in detail exemplary embodiments thereof with reference to the attached drawings, in which:

FIG. 1 is a block diagram of a non-volatile memory device in accordance with an exemplary embodiment of the present inventive concept;

FIG. 2 illustrates a diagram of memory cells of the non-volatile memory device of FIG. 1 in accordance with an exemplary embodiment of the present inventive concept;

FIG. 3 illustrates a memory cell distribution of the non-volatile memory device of FIG. 1 in accordance with an exemplary embodiment of the present inventive concept;

FIG. 4 is a flowchart for explaining a least significant bit (LSB) read operation of the non-volatile memory device of FIG. 1 in accordance with an exemplary embodiment of the present inventive concept;

FIG. 5 is a flowchart for explaining a most significant bit (MSB) read operation of the non-volatile memory device of FIG. 1 in accordance with an exemplary embodiment of the present inventive concept;

FIG. 6 illustrates program voltages applied to memory cells of the non-volatile memory device of FIG. 1 in accordance with an exemplary embodiment of the present inventive concept;

FIGS. 7 to 9 are diagrams for explaining characteristics of maintaining data reliability of the non-volatile memory device of FIG. 1 in accordance with an exemplary embodiment of the present inventive concept;

FIGS. 10 and 11 illustrate program voltages applied to memory cells of the non-volatile memory device of FIG. 1 in accordance with exemplary embodiments of the present inventive concept; and

FIGS. 12 to 14 are diagrams for explaining an application example of the non-volatile memory device of FIG. 1 in accordance with exemplary embodiments of the present inventive concept.

### DETAILED DESCRIPTION OF THE EMBODIMENTS

Exemplary embodiments of the present inventive concept are described more fully hereinafter with reference to the accompanying drawings. The present inventive concept may, however, be embodied in many different forms and should not be construed as being limited to the exemplary embodiments set forth herein. Throughout the specification and drawings, like reference numerals may denote like elements.

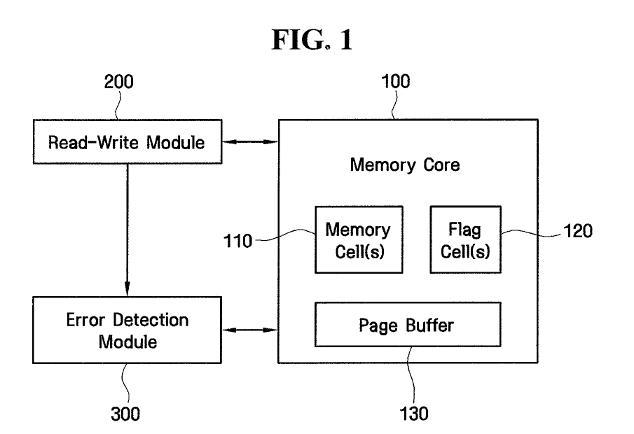

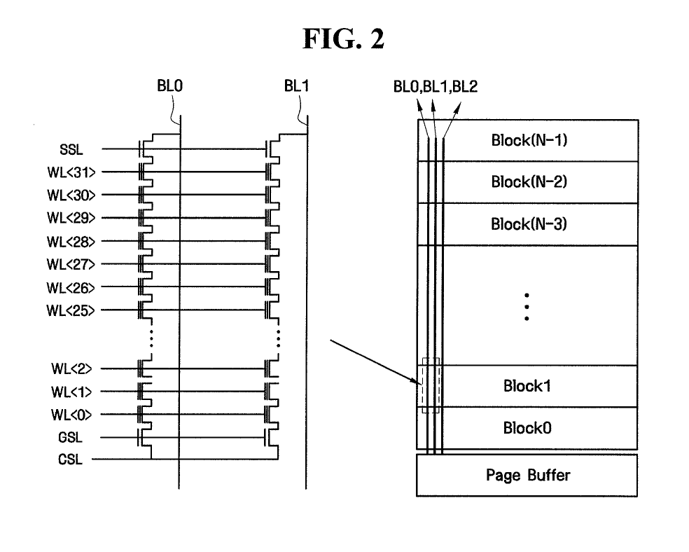

First, a non-volatile memory device in accordance with an exemplary embodiment of the present inventive concept will be described with reference to FIGS. 1 and 2.

FIG. 1 is a block diagram of a non-volatile memory device in accordance with an exemplary embodiment of the present inventive concept. FIG. 2 illustrates a diagram of memory cells of the non-volatile memory device of FIG. 1 in accordance with an exemplary embodiment of the present inventive concept. Although a NAND flash memory is described below as an example of the non-volatile memory device of FIG. 1, the present inventive concept is not limited thereto. Further, although each memory cell of the NAND flash memory described below is a 2-bit multi-level cell, the present inventive concept is not limited thereto.

Referring to FIG. 1, the non-volatile memory device may include a memory core 100, a read-write module 200, and an error detection module 300.

The memory core 100 may include memory cells 110 such as multi-level cells and flag cells 120 indicating whether the memory cells 110 are least significant bit (LSB) programmed or most significant bit (MSB) programmed. In this case, as shown in FIG. 2, the memory cells 110 may be NAND flash memory cells including a plurality of memory blocks Block0 to Block(N−1) having strings sharing bit lines BL0, BL1, BL2.

An expanded view of a part of Block 1 (identified by the dashed rectangle) is shown on the left-hand side of FIG. 2. The expanded view shows adjacent transistor strings connected to the bit lines BL0 and BL1, wherein each string includes a plurality of transistors having their gates connected to word lines WL<0> to WL<31>, a string select transistor having its gate connected to a string select line SSL, and a ground select transistor having its gate connected to a ground select line GSL. A first terminal of the string select transistor is connected to the respective bit line BL0 or BL1, a first terminal of the ground select transistor is connected to a common source line CSL, and the plurality of transistors having their gates connected to the word lines WL<0> to WL<31> are connected in series between a second terminal of each of the string select transistor and the ground select transistor.

The memory core 100 may include a page buffer 130 to program or read data on a page basis, and the page buffer 130 may control the bit lines BL0, BL1, BL2.

Further, the memory core 100 may include an error detection cell (not shown) to check whether programming of the memory cells 110 has been normally performed. The error detection cell (not shown) may be included in the memory core 100, or e.g., in the error detection module 300 outside the memory core 100.

The read-write module 200 may receive a read command and an address from a control circuit (not shown) to control the memory core 100 to perform a LSB read or MSB read operation. Further, the read-write module 200 may receive a write command and an address from the control circuit (not shown) to control the memory core 100 to perform a LSB program or MSB program operation.

In accordance with an exemplary embodiment of the inventive concept, the read-write module 200 may effectuate control such that the memory cell 110 and the error detection cell (not shown) are programmed and the flag cell 120 is not programmed during a first period, and the memory cell 110, the error detection cell (not shown) and the flag cell 120 are programmed during a second period after the first period. Specifically, the read-write module 200 may control the memory cell 110 and the error detection cell (not shown) to be programmed and the flag cell 120 to not be programmed during first to n^{th} (n is a natural number equal to or greater than 1) program loops, and the memory cell 110, the error detection cell (not shown) and the flag cell 120 to be programmed during (n+1)^{th} to m^{th} (m is a natural number greater than n) program loops. In this case, the programming may be MSB programming. The just mentioned programming scheme of the read-write module 200 will be described in detail below, while explaining an operation of the non-volatile memory device according to an exemplary embodiment of the present inventive concept.

The error detection module 300 may detect whether there is an error in the data read from the memory cell 110 in a data read operation. The error detection module 300 may include an error correction code (ECC) circuit, a cyclic redundancy check (CRC) circuit, an error-detecting code (EDC) circuit and the like. The ECC circuit will be described below as an example of the error detection module 300, but the present inventive concept is not limited thereto.

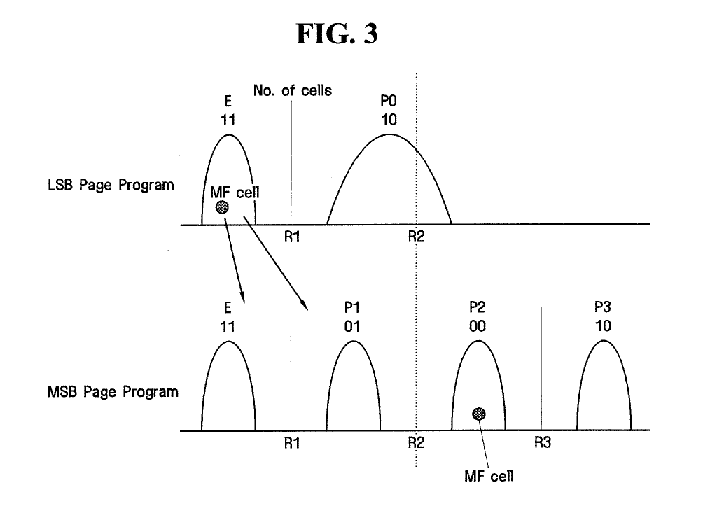

Hereinafter, an operation of the non-volatile memory device of FIG. 1 in accordance with an exemplary embodiment of the present inventive concept will be described with reference to FIGS. 3 to 6.

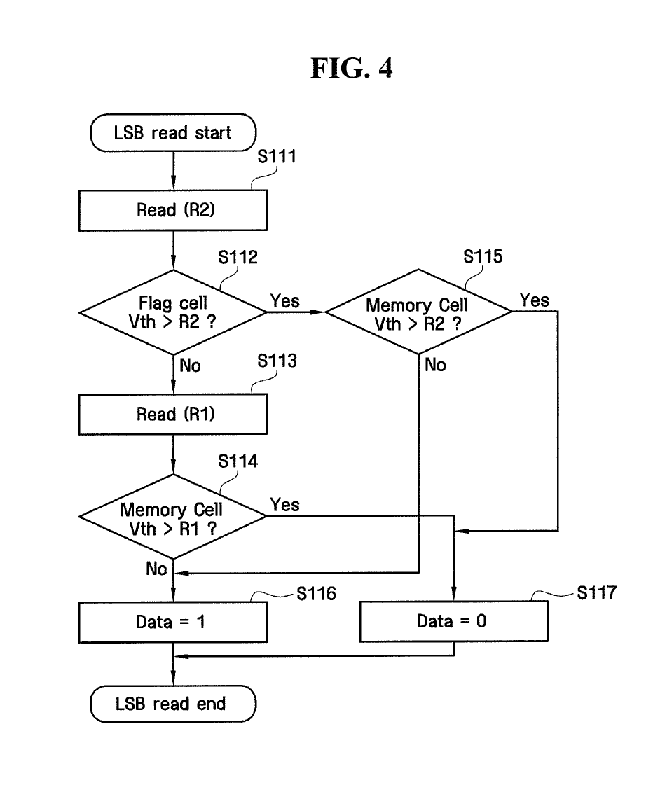

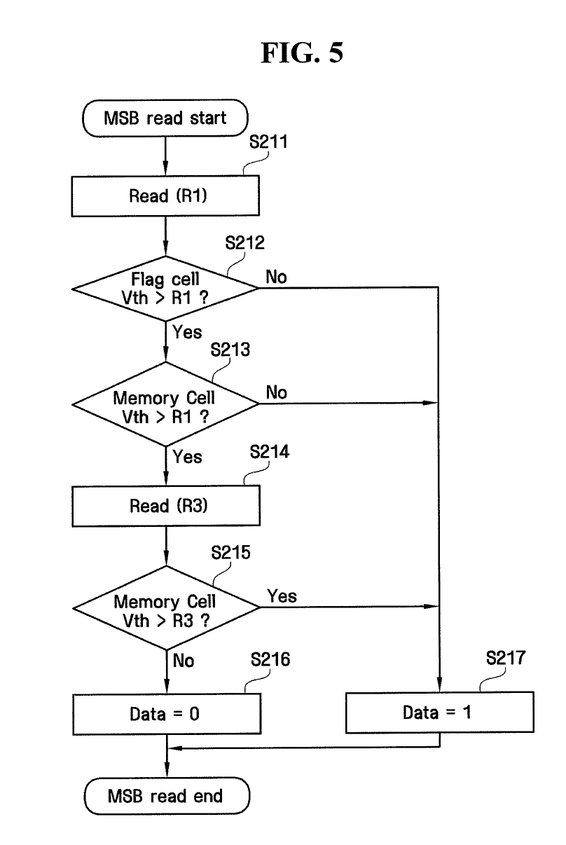

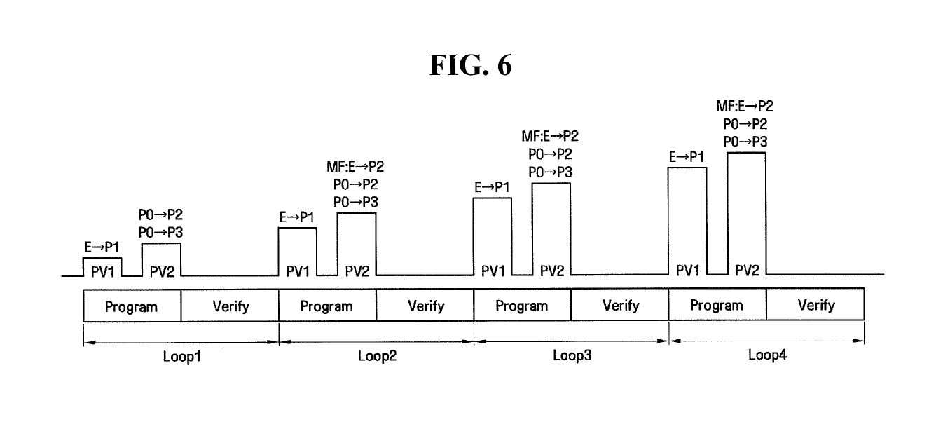

FIG. 3 illustrates a memory cell distribution of the non-volatile memory device of FIG. 1 in accordance with an exemplary embodiment of the present inventive concept. FIG. 4 is a flowchart for explaining a LSB read operation of the non-volatile memory device of FIG. 1 in accordance with an exemplary embodiment of the present inventive concept. FIG. 5 is a flowchart for explaining a MSB read operation of the non-volatile memory device of FIG. 1 in accordance with an exemplary embodiment of the present inventive concept. FIG. 6 illustrates program voltages applied to memory cells of the non-volatile memory device of FIG. 1 in accordance with an exemplary embodiment of the present inventive concept.

Referring to FIG. 3, the 2-bit memory cell has the following two states: a first state where the memory cell is LSB programmed, and a second state where the memory cell is MSB is programmed.

First, referring to FIG. 3, a program process of the 2-bit memory cell is as follows. If data to be programmed is ‘10’, ‘0’ is LSB data and ‘1’ is MSB data. When a LSB program operation is performed on the memory cell in an erase state, the memory cell has ‘11’ state E or ‘10’ state P0 according to threshold voltage levels. In this case, a first read voltage R1 may be set between the ‘11’ state E and ‘10’ state P0.

Then, when the MSB program operation is performed, the memory cell of the ‘10’ state P0 is programmed to ‘00’ state P2 or ‘10’ state P3, and the memory cell of the ‘11’ state E is programmed to ‘01’ state P1. In this case, the first read voltage R1 may be set between the ‘11’ state E and the ‘01’ state P1, a second read voltage R2 may be set between the ‘01’ state P1 and the ‘00’ state P2, and a third read voltage R3 may be set between the ‘00’ state P2 and the ‘10’ state P3.

In this case, a flag cell MF is a memory cell for determining whether a certain page has been MSB programmed. In other words, it is determined whether the page has been LSB programmed or MSB programmed according to the position of the flag cell MF. Although a case where the flag cell MF is programmed to the ‘00’ state P2, which indicates the memory cell is MSB programmed, is illustrated in FIG. 3, the present inventive concept is not limited thereto. For example, the flag cell MF may be programmed to the ‘10’ state P3 to indicate the memory cell is MSB programmed.

Next, referring to FIGS. 4 and 5, a read process of the 2-bit memory cell is as follows. Upon receipt of a read command and an address (e.g., a page address) from the control circuit (not shown), the NAND flash memory performs a LSB read operation or MSB read operation. Generally, a page address includes a LSB page address or MSB page address. Accordingly, in response to the inputted read command and address, the NAND flash memory determines whether a LSB read operation or MSB read operation will be performed on a certain page, and then performs the determined read operation.

Referring to FIGS. 3 and 4, a LSB read operation of the NAND flash memory is as follows.

The NAND flash memory determines that it is a LSB read operation according to the inputted read command and address, and reads data of a page including the memory cell to be read using the second read voltage R2 (S111). The page also includes a flag cell indicating whether the page has been LSB programmed or MSB programmed.

It is determined whether a threshold voltage Vth of the flag cell is greater than the second read voltage R2 (S112). If the page has been LSB programmed, the threshold voltage Vth of the flag cell may not be greater than the second read voltage R2. On the other hand, if the page has been MSB programmed, the threshold voltage Vth of the flag cell may be greater than the second read voltage R2.

If the threshold voltage Vth of the flag cell is not greater than the second read voltage R2 (based on the determination of S112), the NAND flash memory reads data of the page using the first read voltage R1 (S113). In other words, if the page has been LSB programmed, the NAND flash memory reads data of the page again, but this time using the first read voltage R1.

Then, it is determined whether a threshold voltage Vth of the memory cell of the page is greater than the first read voltage R1 (S114). Accordingly, the NAND flash memory determines whether the threshold voltage Vth of the memory cell to be read is greater than the first read voltage R1, and then determines LSB data of the memory cell.

If the threshold voltage Vth of the flag cell is greater than the second read voltage R2 (based on the determination of S112), it is determined whether the threshold voltage Vth of the memory cell of the page is greater than the second read voltage R2 (S115). In other words, if the page has been MSB programmed, it is determined whether the threshold voltage Vth of the memory cell to be read is greater than the second read voltage R2 to thereby determine LSB data of the memory cell.

If the threshold voltage Vth of the memory cell is not greater than the first read voltage R1 (based on the determination of S114), it is determined that the memory cell stores ‘1’ of LSB data (S116). Further, if the threshold voltage Vth of the memory cell is not greater than the second read voltage R2 (based on the determination of S115), it is determined that the memory cell stores ‘1’ of LSB data (S116).

If the threshold voltage Vth of the memory cell is greater than the first read voltage R1 (based on the determination of S114), it is determined that the memory cell stores ‘0’ of LSB data (S117). Further, if the threshold voltage Vth of the memory cell is greater than the second read voltage R2 (based on the determination of S115), it is determined that the memory cell stores ‘0’ of LSB data (S117).

Next, referring to FIGS. 3 and 5, a MSB read operation of the NAND flash memory is as follows.

The NAND flash memory determines that it is a MSB read operation according to the inputted read command and address, and reads data of a page including the memory cell using the first read voltage R1 (S211). The page also includes a flag cell indicating whether the page has been LSB programmed or MSB programmed.

The NAND flash memory determines whether a threshold voltage Vth of the flag cell is greater than the first read voltage R1 (S212). If the page has been LSB programmed, the threshold voltage Vth of the flag cell may not be greater than the first read voltage R1. On the other hand, if the page has been MSB programmed, the threshold voltage Vth of the flag cell may be greater than the first read voltage R1.

If the threshold voltage Vth of the flag cell is greater than the first read voltage R1 (based on the determination of S212), the NAND flash memory determines whether the threshold voltage Vth of the memory cell to be read is greater than the first read voltage R1 (S213).

If the threshold voltage Vth of the memory cell is greater than the first read voltage R1 (based on the determination of S213), the NAND flash memory reads data of the page again, but this time using the third read voltage R3 (S214).

Then, it is determined whether the threshold voltage Vth of the memory cell to be read is greater than the third read voltage R3 (S215).

If the threshold voltage Vth of the memory cell is not greater than the third read voltage R3 (based on the determination of S215), it is determined that the memory cell stores ‘0’ of MSB data (S216).

If the threshold voltage Vth of the flag cell is smaller than the first read voltage R1 (based on the determination of S212), it is determined that the memory cell stores ‘1’ of MSB data (S217). If the threshold voltage Vth of the memory cell is smaller than the first read voltage R1 (based on the determination of S213), it is determined that the memory cell stores ‘1’ of MSB data (S217). If the threshold voltage Vth of the memory cell is greater than the third read voltage R3 (based on the determination of S215), it is determined that the memory cell stores ‘1’ of MSB data (S217).

In this case, to MSB program the memory cell (110 of FIG. 1) and the flag cell (120 of FIG. 1) included in the memory core (100 of FIG. 1), the read-write module (200 of FIG. 1) of the non-volatile memory device of FIG. 1 applies program voltages having a plurality of program loops, in accordance with an exemplary embodiment of the inventive concept as shown in FIG. 6, to the memory core (100 of FIG. 1).

Specifically, referring to FIG. 6, each of program loops Loop1 to Loop4 includes a program section and a verify section. In each program section, a first program voltage PV1 and a second program voltage PV2 are applied to the memory core (100 of FIG. 1). In this case, the first program voltage PV1 of the first program loop Loop1 programs the memory cell of the ‘11’ state E to the ‘01’ state P1. Further, the second program voltage PV2 of the first program loop Loop1 programs the memory cell of the ‘10’ state P0 to the ‘00’ state P2 or ‘10’ state P3. In this case, the second program voltage PV2 of the first program loop Loop1 prevents the flag cell MF from being programmed such that the flag cell MF is not programmed to the ‘00’ state P2 during the first program loop Loop1.

Next, the first program voltage PV1 of the second to fourth program loops Loop2 to Loop4 programs the memory cell of the ‘11’ state E to the ‘01’ state P1. Further, the second program voltage PV2 of the second to fourth program loops Loop2 to Loop4 programs the flag cell MF to the ‘00’ state P2, and programs the memory cell of the ‘10’ state P0 to the ‘00’ state P2 or ‘10’ state P3. In other words, the flag cell MF is not programmed in the first program loop Loop1, but is programmed from the second program loop Loop2.

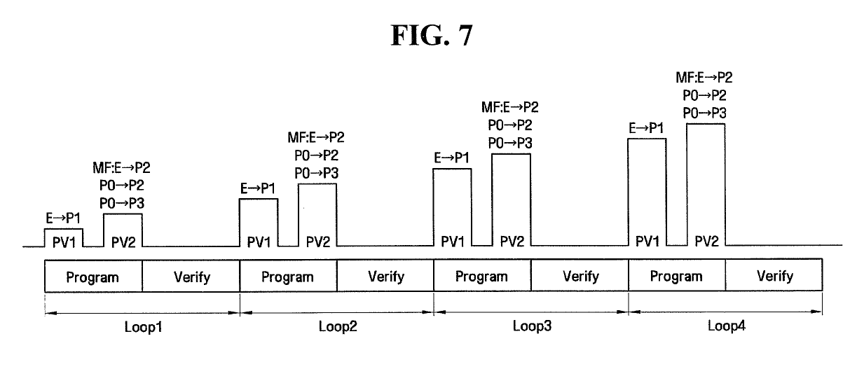

Meanwhile, in each verify section, although omitted in FIG. 6 to clarify the difference between the program voltages PV1 and PV2, a specific verify voltage is applied to the memory core (100 of FIG. 1) to verify whether programming has been normally performed in each program section. The same is applicable to the other cases shown in FIGS. 7, 10 and 11.

As described above, when the memory core (100 of FIG. 1) is MSB programmed to prevent the flag cell MF from being programmed in the first program loop Loop1 and program the flag cell MF from the second program loop Loop2, it is possible to ensure the reliability of data in the event of a sudden power-off of the non-volatile memory device. The reason for this will be described below in detail with reference to FIGS. 7 to 9.

FIGS. 7 to 9 are diagrams for explaining characteristics of maintaining data reliability of the non-volatile memory device of FIG. 1 in accordance with an exemplary embodiment of the present inventive concept.

First, let us suppose that the program voltages shown in FIG. 7 are applied to MSB program the memory core (100 of FIG. 1). In other words, the program voltages shown in FIG. 7 include the first program voltage PV1 to program the memory cell of the ‘11’ state E to the ‘01’ state P1, and the second program voltage PV2 to program the flag cell MF to the ‘00’ state P2 and program the memory cell of the ‘10’ state P0 to the ‘00’ state P2 or ‘10’ state P3 in each of the program loops Loop1 to Loop4.

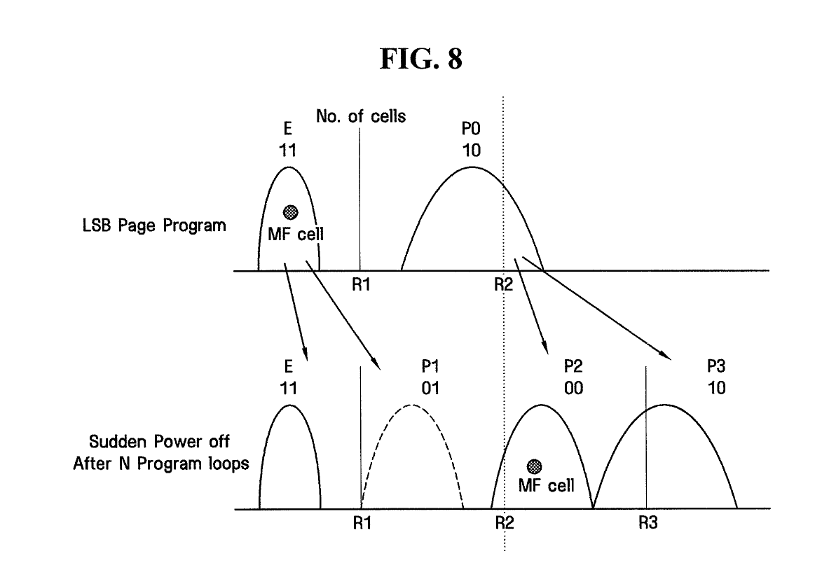

If sudden a power-off occurs after many program loops (e.g., N (greater than n) program loops), data distribution of memory cells may look like that shown in FIG. 8. In this case, when a MSB read operation is performed, MSB data of the memory cells between the first read voltage R1 and the third read voltage R3 is read as ‘0’, but remains in a state where the programming is interrupted with MSB ECC data. Accordingly, the read MSB data is determined as uncorrectable data, and a memory controller or external chip controller may recognize such as a MSB data error to perform a series of predetermined data backup operations, thereby ensuring data reliability.

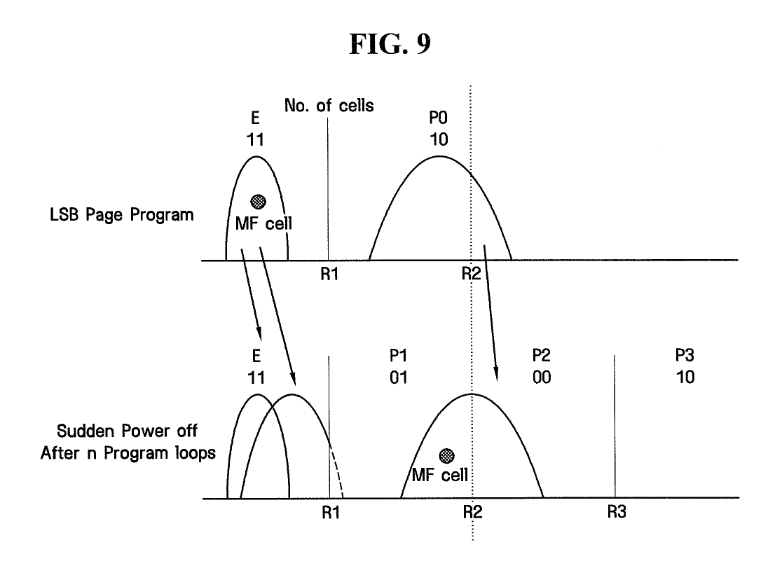

On the other hand, if a sudden power-off occurs after few program loops (e.g., n (smaller than N) program loops), since only some of the memory cells are programmed from the ‘11’ state E to the ‘01’ state P1, data distribution of memory cells may look like that shown in FIG. 9. In this case, since ECC data for a LSB stored in the error detection cell is small compared to the memory cell, it may not be programmed stochastically. In this case, when a LSB read operation is performed, first, since the flag cell MF determined at the second read voltage R2 has an erased state, the LSB read operation is performed by updating at the first read voltage R1. Consequently, since only some of the memory cells are programmed from the ‘11’ state E to the ‘01’ state P1, it is determined as ECC correctable data. Then, when a MSB read operation is performed, since a read operation is performed at the first read voltage R1 and the flag cell MF has been programmed, it is recognized that MSB data has been programmed. Accordingly, the read operation is performed using the third read voltage R3, and MSB data of the memory cells ranging from the first read voltage R1 to the second read voltage R2 is recognized as ‘0’. Further, data outside the range is recognized as V. Consequently, it is read as the same data as the previous LSB data, and LSB ECC data originally applied to the LSB data is read as MSB ECC data. Accordingly, it is determined as ECC correctable data. In other words, a MSB data error is not recognized due to occurrence of a sudden power-off.

In this case, let us suppose that n is 1, and the program voltages are applied to the memory core (100 of FIG. 1) as shown in FIG. 6 (rather than in the manner shown in FIG. 7) to prevent the flag cell MF from being programmed in the first program loop Loop1 and program the flag cell MF from the second program loop Loop2.

If a sudden power-off occurs in the first program loop Loop1, since the flag cell MF is recognized as an erased cell because it has not been programmed, although a MSB read operation is performed, it is not recognized that MSB data is programmed in the memory cell. Further, if a sudden power-off occurs after many program loops (e.g., R (greater than r) program loops), as described above, the read MSB data is determined as uncorrectable data. Accordingly, such a MSB data error may be recognized by a memory controller or external chip controller. In other words, even though sudden a power-off occurs, it is possible to ensure data reliability.

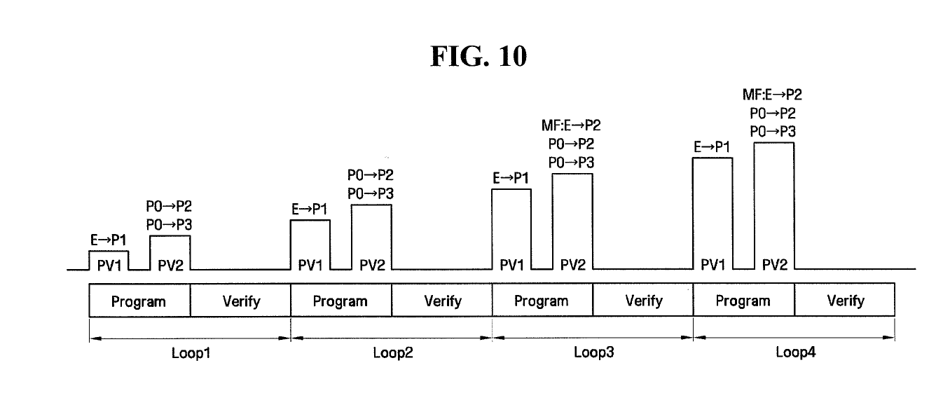

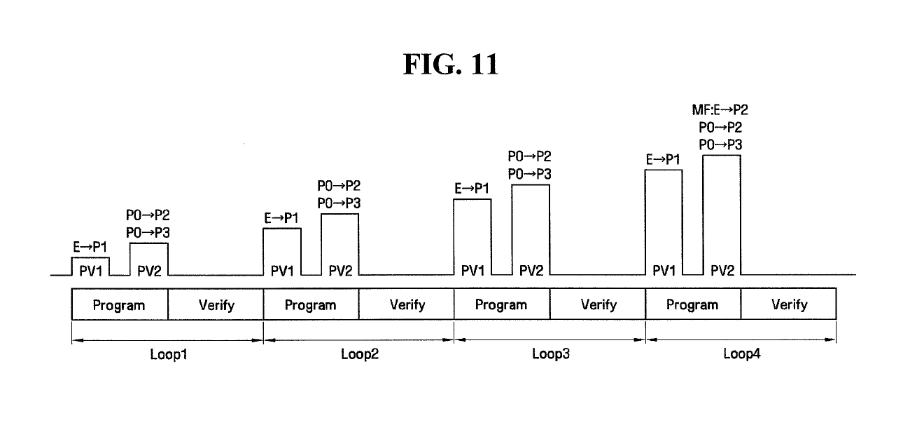

Hereinafter, the non-volatile memory device of FIG. 1 will be described with reference to FIGS. 10 and 11.

FIGS. 10 and 11 illustrate program voltages applied to memory cells of the non-volatile memory device in accordance with exemplary embodiments of the present inventive concept. The following description will focus on differences between the program voltages of FIGS. 10 and 11 and those discussed above without repeated description.

Referring to FIG. 10, the read-write module (200 of FIG. 1) applies program voltages having a plurality of program loops, in accordance with an exemplary embodiment of the inventive concept as shown in FIG. 10, to the memory core (100 of FIG. 1).

Specifically, referring to FIG. 10, each of program loops Loop1 to Loop4 includes a program section and a verify section. In each program section, a first program voltage PV1 and a second program voltage PV2 are applied to the memory core (100 of FIG. 1). In this case, the first program voltage PV1 of the first program loop Loop1 programs the memory cell of the ‘11’ state E to the ‘01’ state P1. The first program voltage PV1 of the second program loop Loop2 also programs the memory cell of the ‘11’ state E to the ‘01’ state P1. Further, the second program voltage PV2 of the first program loop Loop1 programs the memory cell of the ‘10’ state P0 to the ‘00’ state P2 or ‘10’ state P3. The second program voltage PV2 of the second program loop Loop2 also programs the memory cell of the ‘10’ state P0 to the ‘00’ state P2 or ‘10’ state P3. In this case, the second program voltage PV2 of the first and second program loops Loop1 and Loop2 prevents the flag cell MF from being programmed such that the flag cell MF is not programmed to the ‘00’ state P2 in the first and second program loops Loop1 and Loop2.

Next, the first program voltage PV1 of the third and fourth program loops Loop3 and Loop4 programs the memory cell of the ‘11’ state E to the ‘01’ state P1. Further, the second program voltage PV2 of the third and fourth program loops Loop3 and Loop4 programs the flag cell MF to the ‘00’ state P2, and programs the memory cell of the ‘10’ state P0 to the ‘00’ state P2 or ‘10’ state P3. In other words, the flag cell MF is not programmed in the first and second program loops Loop1 and Loop2, but is programmed from the third program loop Loop3. The non-volatile memory device of FIG. 1, which employs the programming scheme of FIG. 10 in accordance with an exemplary embodiment of the present inventive concept, has data reliability when a sudden power-off occurs in the first and second program loops Loop1 and Loop2 for at least the same reasons described above.

Although the above-described exemplary embodiments of the present inventive concept program the flag cell MF from the second program loop Loop2 or the third program loop Loop3, the flag cell MF may be programmed at various points. For example, as shown in FIG. 11, the flag cell MF is programmed from the fourth program loop Loop4, to ensure data reliability of the non-volatile memory device of FIG. 1 when a sudden power-off occurs in the first to third program loops Loop1 to Loop3.

In accordance with the exemplary embodiments of the inventive concept described above, the memory cell 110 is programmed and the flag cell 120 is not programmed during first to n^{th} (n is a natural number equal to or greater than 1) program loops, and the memory cell 110 and the flag cell 120 are programmed during (n+1)^{th} to m^{th} (m is a natural number greater than n) program loops. Accordingly, it is possible to ensure data reliability of the non-volatile memory device of FIG. 1 even if a sudden power-off occurs in the first to n^{th} program loops.

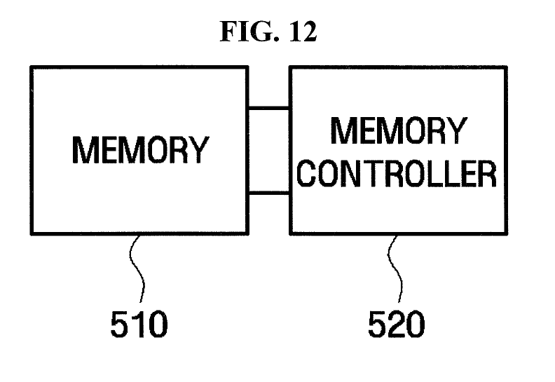

Hereinafter, an application example of the non-volatile memory device of FIG. 1 in accordance with exemplary embodiment of the present inventive concept will be described with reference to FIGS. 12 to 14.

Referring to FIG. 12, a system in accordance with an exemplary embodiment of the present inventive concept includes a memory device 510 and a memory controller 520 connected to the memory device 510. In this case, the memory device 510 may be the non-volatile memory device of FIG. 1, which is a memory device capable of ensuring data reliability in the event of a sudden power-off as described above. The memory controller 520 may provide an input signal for controlling an operation of the memory device 510, e.g., a command signal and an address signal for controlling a read operation and a write operation, to the memory device 510.

The system including the memory device 510 and the memory controller 520 may be embodied in a card such as a memory card. Specifically, the system in accordance with the exemplary embodiment of the present inventive concept may be embodied in a card which satisfies a specified industry standard and is used in an electronic device such as a mobile phone, a two-way communication system, a one-way pager, a two-way pager, a personal communication system, a portable computer, a personal data assistant (PDA), an audio and/or video player, a digital and/or video camera, a navigation system, a global positioning system (GPS), and the like. However, the system is not limited thereto, and it may be embodied in various forms such as a memory stick.

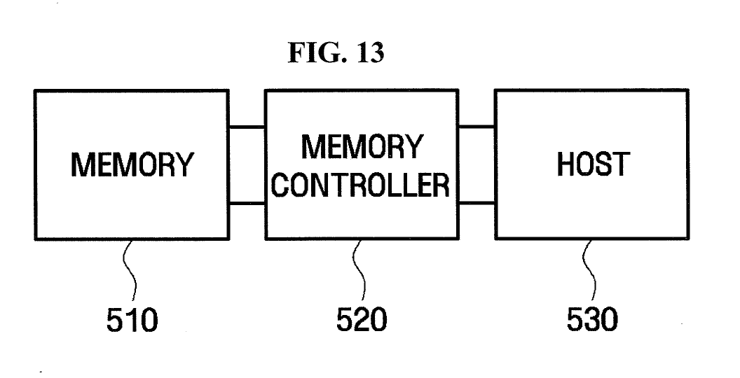

Referring to FIG. 13, a non-volatile memory system in accordance with an exemplary embodiment of the present inventive concept may include a memory device 510, a memory controller 520, and a host system 530. In this case, the host system 530 may be connected to the memory controller 520 via a bus and the like, and provide a control signal to the memory controller 520, so that the memory controller 520 can control an operation of the memory device 510. The host system 530 may be, for example, a processing system used in a mobile phone, a two-way radio communication system, a one-way pager, a two-way pager, a personal communication system, a portable computer, a PDA, an audio and/or video player, a digital and/or video camera, a navigation system, a GPS, and the like.

Although the memory controller 520 is interposed between the memory device 510 and the host system 530 in FIG. 13, it does not have to be. For example, the memory controller 520 may be omitted from a system in accordance with an exemplary embodiment of the present inventive concept.

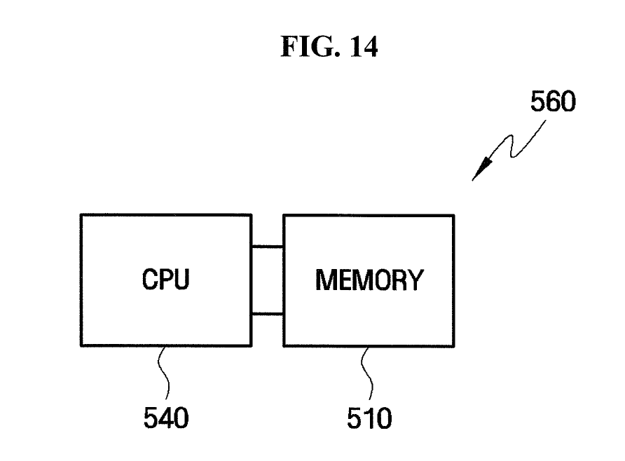

Referring to FIG. 14, a system in accordance with an exemplary embodiment of the present inventive concept may be a computer system 560 including a central processing unit (CPU) 540 and a memory device 510. In the computer system 560, the memory device 510 may be connected to the CPU 540 directly or using a typical computer bus architecture. The memory device 510 may store an operation system (OS) instruction set, a basic input/output start up (BIOS) instruction set, an advanced configuration and power interface (ACPI) instruction set and the like, or may be used as a large-capacity storage device such as a solid state disk (SSD).

For convenience of explanation, all components included in the computer system 560 are not illustrated in FIG. 14. Further, the memory controller 520 is not included between the memory device 510 and the CPU 540 in FIG. 14. However, the memory controller 520 may be interposed between the memory device 510 and the CPU 540 in an exemplary embodiment of the present inventive concept.

While the present inventive concept has been particularly shown and described with reference to exemplary embodiments thereof, it will be understood by those of ordinary skill in the art that various changes in form and detail may be made therein without departing from the spirit and scope of the present inventive concept as defined by the following claims.

What is claimed is:

1. A method for operating a non-volatile memory device, comprising:
programming a memory cell and not programming a flag cell during first to n^{th} (n is a natural number equal to or greater than 1) program loops; and
programming the memory cell and the flag cell during (n+1)^{th} to m^{th} (m is a natural number greater than n) program loops.

2. The method of claim 1, further comprising programming an error detection cell during the first to n^{th} program loops.

3. The method of claim 1, wherein the memory cell includes a 2-bit multi-level cell.

4. The method of claim 3, wherein the memory cell has ‘11’, ‘10’, ‘00’ and ‘01’ states, a first read voltage is set between the ‘11’ state and the ‘01’ state, a second read voltage is set between the ‘01’ state and the ‘00’ state, a third read voltage is set between the ‘00’ state and the ‘10’ state,
the memory cell has the ‘11’ or ‘10’ state in a least significant bit (LSB) programming, and
the memory cell has the ‘11’, ‘10’, ‘00’ or ‘01’ state in a most significant bit (MSB) programming.

5. The method of claim 4, wherein in the MSB programming, a threshold voltage of the flag cell is greater than the second read voltage.

6. The method of claim 4, wherein the flag cell determines whether the memory cell has been MSB programmed.

7. The method of claim 4, wherein each of the first to m^{th} program loops includes a program section and a verify section, and
a first program voltage and a second program voltage are applied to the memory cell during the program section.

8. The method of claim 7, wherein the first program voltage programs the memory cell from the ‘11’ state to the ‘01’ state, and
the second program voltage programs the memory cell from the ‘10’ state to the ‘00’ or ‘10’ state.

9. The method of claim 4, further comprising reading LSB data of the memory cell, wherein the reading comprises:
comparing a threshold voltage of the flag cell with the second read voltage;
comparing a threshold voltage of the memory cell with the first read voltage if the threshold voltage of the flag cell is not greater than the second read voltage; and
comparing the threshold voltage of the memory cell with the second read voltage if the threshold voltage of the flag cell is greater than the second read voltage.

10. The method of claim 9, wherein if the threshold voltage of the memory cell is greater than the first read voltage the LSB data read from the memory cell is ‘0,’ if the threshold voltage of the memory cell is not greater than the first read voltage the LSB data read from the memory cell is ‘1,’ if the threshold voltage of the memory cell is greater than the second read voltage the LSB data read from the memory cell is ‘0,’ or if the threshold voltage of the memory cell is not greater than the second read voltage the LSB data read from the memory cell is ‘1.’

11. The method of claim 4, further comprising reading MSB data of the memory cell, wherein the reading comprises:
comparing a threshold voltage of the flag cell with the first read voltage;
comparing a threshold voltage of the memory cell with the first read voltage if the threshold voltage of the flag cell is greater than the first read voltage; and
comparing the threshold voltage of the memory cell with the third read voltage if the threshold voltage of the memory cell is greater than the first read voltage.

12. The method of claim 11, wherein if the threshold voltage of the memory cell is not greater than the third read voltage the MSB data read from the memory cell is ‘0’, if the threshold voltage of the flag cell is not greater than the first read voltage the MSB data read from the memory cell is ‘1,’ if the threshold voltage of the memory cell is not greater than the first read voltage the MSB data read from the memory cell is ‘1,’ or if the threshold voltage of the memory cell is greater than the third read voltage the MSB data read from the memory cell is ‘1.’

13. The method of claim 1, wherein the programming includes most significant bit (MSB) programming.

14. The method of claim 1, wherein the memory cell includes a NAND flash memory cell.

15. A method for operating a non-volatile memory device, comprising:
programming a memory cell and not programming a flag cell during a first period; and
programming the memory cell and the flag cell during a second period after the first period.

16. The method of claim 15, wherein the memory cell includes a 2-bit memory cell.

17. The method of claim 16, wherein the memory cell has ‘11’, ‘10’, ‘00’ and ‘01’ states, a first read voltage is set between the ‘11’ state and the ‘01’ state, a second read voltage is set between the ‘01’ state and the ‘00’ state, a third read voltage is set between the ‘00’ state and the ‘10’ state,
the memory cell has the ‘11’ or ‘10’ state in a least significant bit (LSB) programming, and
the memory cell has the ‘11’, ‘10’, ‘00’ or ‘01’ state in a most significant bit (MSB) programming.

18. The method of claim 17, wherein the flag cell determines whether the memory cell has been MSB programmed.

19. A non-volatile memory device, comprising:
a memory core including a memory cell and a flag cell; and
a read-write module, wherein the read-write module programs the memory cell and prevents the flag cell from being programmed during first to n^{th} (n is a natural number equal to or greater than 1) program loops, and programs the memory cell and the flag cell) during (n+1)^{th} to m^{th} (m is a natural number greater than n) program loops.

20. The non-volatile memory device of claim 19, wherein the memory cell includes a NAND flash memory cell and the NAND flash memory cell stores 2 or more bits.
